(19) United States
(12) Patent Application Publication
(10) Pub. No.: US 2002/0009899 A1
(43) Pub. Date: Jan. 24, 2002

(54) Method and device for manufacturing semiconductor devices including insulation oxide layers

(75) Inventor: Yoshimi Shiramizu, Tokyo (JP)

Correspondence Address: SUGHRUE, MION, ZINN, MACPEAK & SEAS, PLLC, 2100 Pennsylvania Avenue, N.W., Washington, DC, 20037-3213, US

(73) Assignee: NEC CORPORATION

(21) Appl. No.: 09/968,273

(22) Filed: Oct. 2, 2001

Related U.S. Application Data
(62) Division of application No. 09/627,296, filed on Jul. 27, 2000.

(30) Foreign Application Priority Data
Jul. 29, 1999 (JP) 215945/1999

(51) Int. Cl. H01L 21/31

(52) U.S. Cl. 438/770

(57) ABSTRACT

In a manufacturing method of a semiconductor device including insulation oxide layers (gate oxide layers etc.), before a step for forming an insulation oxide layer on a semiconductor circuit board, the semiconductor circuit board is held in an atmosphere containing oxygen gas (N₂ (99% (volume))+O₂ (1% (volume)), for example) at temperature X (400° C.<X<750° C.) for a preset period. Preferably, the preset period for the holding step is set between 5 minutes and 10 minutes, and the concentration of the oxygen gas in the oxygen-containing atmosphere is set between 0.5% (volume) and 1.0% (volume). By the holding step at the temperature X (400° C.<X<750° C.), organic impurities (adipates etc.) adhering to the surface of the semiconductor circuit board can be removed effectively, thereby very thin and uniform insulation oxide layers having high insulation resistance can be formed on the semiconductor circuit board, and thereby a semiconductor device having satisfactory electrical characteristics and reliability can be manufactured. The efficiency of the removal of the organic impurities can be enhanced by executing VUV (Vacuum UltraViolet) light irradiation in the holding step by use of a 172 nm xenon excimer lamp etc.

### BACKGROUND OF THE INVENTION

The present invention relates to a manufacturing method and a manufacturing device for a semiconductor device, and in particular, to a semiconductor device manufacturing method concerning the formation of an insulation oxide layer (gate oxide layer etc.) and a semiconductor device manufacturing device for forming an insulation oxide layer on a semiconductor circuit board.

### Description of the Prior Art

With the progress of higher levels of integration of VLSI (Very Large Scale Integration) chips, there is a growing need for a technique capable of cleaning the surface of a semiconductor circuit board (substrate) effectively. If impurities adhering to the surface of the semiconductor circuit board existed before a stage for heat-treating the semiconductor circuit board for forming a gate oxide layer thereon, a uniform gate oxide layer can not be formed on the semiconductor circuit board, thereby electrical characteristics and reliability of the semiconductor device (which is implemented by the semiconductor circuit board) are necessitated to be deteriorated. Therefore, the impurities on the surface of the semiconductor circuit board have to be removed almost perfectly before the formation of the gate oxide layer.

These days, it is becoming evident that organic substances existing in the atmosphere of a clean room deteriorate the electrical characteristics of a semiconductor device which is manufactured in the clean room. Such organic substances are emitted as gas molecules from materials of the walls of the clean room, tool boxes, clothes, cosmetics, hair conditioners, etc. It is very difficult to perfectly prevent such organic substances from adhering to semiconductor circuit boards in the clean room, therefore, the adhesion of the organic substances is almost inevitable. Meanwhile, the thickness of the gate oxide layer is becoming thinner and thinner these days, and thus reduction of the organic impurities on the semiconductor circuit board is becoming more critical. In other words, as the thickness of the gate oxide layer gets thinner, the formation of the gate oxide layer having a uniform thickness is disturbed by smaller amounts of organic impurities. Therefore, the removal of the organic substances from the semiconductor circuit board before the formation of the gate oxide layer is essential and imperative.

Many of the organic substances have boiling points of lower than 400° C., therefore, it seems that the organic substances adhering to the surface of the semiconductor circuit board can easily be removed in an inert gas atmosphere such as a nitrogen gas atmosphere at a temperature around 400° C. However, such organic impurities are bonding to the surface of the semiconductor circuit board by chemical adsorption, and thus can not be removed effectively only by holding the semiconductor circuit board in an inert gas atmosphere around 400° C. On the other hand, it also seems possible to remove the organic substances on the surface by holding the semiconductor circuit board in a high temperature environment, however, the organic substances can not be removed only by raising the temperature. For example, in the inert gas atmosphere, there are cases where the organic substances can not be removed from the surface of the semiconductor circuit board at a temperature above 800° C. (temperature for the formation of the gate oxide layers), due to recombination of Si-C.

In order to resolve the problems, the present inventor has been proposed a semiconductor device manufacturing method for removing the organic substances from the surface of the semiconductor circuit board in Japanese Patent Application Laid-Open No.HEI11-162975. In the document, the present inventor has found and proposed a method for removing the organic substances from the surface of the semiconductor circuit board as follows. First, the semiconductor circuit board is put in a furnace at a temperature between room temperature and below 400° C. and the furnace is filled with an atmosphere containing oxygen gas. Subsequently, the temperature inside the furnace is raised to 400° C., and thereafter the semiconductor circuit board is held in the oxygen-containing atmosphere at 400° C. for a preset period, thereby the organic substances adhering to the surface of the semiconductor circuit board could be removed. By holding the semiconductor circuit board in the oxygen-containing atmosphere, the organic substances are decomposed by the oxygen in the atmosphere, and thereby the organic impurities on the surface of the semiconductor circuit board can be removed easily and efficiently.

However, when the present inventor conducted a qualitative analysis concerning impurities on the surface of the semiconductor circuit board by use of a mass spectrometer, organic substances which have not been paid attention to (adipates) was found. The boiling points of the organic substances (adipates) are high (above 450° C.) and chemical bonding powers of them are higher than those of conventional ordinary organic impurities, and thus the adipates can not be removed by the method of Japanese Patent Application Laid-Open No.HEI11-162975, that is, by holding the semiconductor circuit board in an oxygen-containing atmosphere at a temperature around 400° C. for a preset period. If a semiconductor device is manufactured by forming gate oxide layers on a semiconductor circuit board with such organic substances adhering thereto, the gate oxide layers are necessitated to have poor electrical characteristics and low long-term reliability, and thus a semiconductor device having satisfactory electrical characteristics and high reliability can hardly be obtained. Especially when the gate oxide layer is thin, the effects of the impurities become larger as the thickness of the gate oxide layer becomes thinner. Therefore, if the impurities can not be removed almost perfectly, it is very difficult to obtain thin gate oxide layers having satisfactory electrical characteristics and reliability.

### SUMMARY OF THE INVENTION

It is therefore the primary object of the present invention to provide a manufacturing method and a manufacturing device for a semiconductor device, by which insulation oxide layers (gate oxide layers etc.) of satisfactory electrical characteristics and reliability can be formed on a semiconductor circuit board and thereby a semiconductor device having satisfactory electrical characteristics and reliability can be manufactured.

In accordance with a first aspect of the present invention, there is provided a manufacturing method of a semiconductor device including a step for forming an insulation oxide layer on a semiconductor circuit board. In the manufacturing method, before the insulation oxide layer formation step, the semiconductor circuit board is held in an atmosphere containing oxygen gas at temperature X (400° C.<X<750° C.) for a preset period.

In accordance with a second aspect of the present invention, in the first aspect, the preset period is set between 5 minutes and 10 minutes.

In accordance with a third aspect of the present invention, in the first aspect, the concentration of the oxygen gas in the oxygen-containing atmosphere is set between 0.5% (volume) and 1.0% (volume).

In accordance with a fourth aspect of the present invention, in the first aspect, the temperature X is set so as to be suitable for removing adipates which are found on the surface of the semiconductor circuit board.

In accordance with a fifth aspect of the present invention, in the fourth aspect, the temperature X is set so as to be suitable for removing DBA (di-butyl adipate).

In accordance with a sixth aspect of the present invention, in the fourth aspect, the temperature X is set so as to be suitable for removing DOA (DEHA) (di-2-ethylhexyl adipate).

In accordance with a seventh aspect of the present invention, in the first aspect, the temperature X is set between 450° C. and 700° C.

In accordance with an eighth aspect of the present invention, in the seventh aspect, the temperature X is set between 500° C. and 650° C.

In accordance with a ninth aspect of the present invention, in the first aspect, after the step for holding the semiconductor circuit board in the oxygen-containing atmosphere at the temperature X for the preset period, the temperature of the semiconductor circuit board is raised to Y (800° C.≦Y≦850° C.) in an inert gas atmosphere, and thereafter the semiconductor circuit board is held in an oxygen-abundant atmosphere at the temperature Y for a preset period so that the insulation oxide layer will be formed on the surface of the semiconductor circuit board.

In accordance with a tenth aspect of the present invention, in the first aspect, before the step for holding the semiconductor circuit board in the oxygen-containing atmosphere at the temperature X for the preset period, the semiconductor circuit board is held in an atmosphere containing oxygen gas at temperature around 400° C. for a preset period.

In accordance with an eleventh aspect of the present invention, in the first aspect, in the step for holding the semiconductor circuit board in the oxygen-containing atmosphere at the temperature X for the preset period, the semiconductor circuit board is irradiated with VUV (Vacuum UltraViolet) light.

In accordance with a twelfth aspect of the present invention, in the eleventh aspect, the VUV light irradiation is executed by use of a xenon excimer lamp whose center wavelength is 172 nm.

In accordance with a thirteenth aspect of the present invention, in the twelfth aspect, the VUV light irradiation is executed for a period between 5 seconds and 60 seconds.

In accordance with a fourteenth aspect of the present invention, in the eleventh aspect, the concentration of the oxygen gas in the oxygen-containing atmosphere is set to approximately 20% (volume) when the VUV light irradiation is executed.

In accordance with a fifteenth aspect of the present invention, in the first aspect, before the step for holding the semiconductor circuit board in the oxygen-containing atmosphere at the temperature X for the preset period, the semiconductor circuit board placed in an oxygen-containing atmosphere is irradiated with VUV (Vacuum UltraViolet) light at temperature between room temperature and 400° C. for a preset period.

In accordance with a sixteenth aspect of the present invention, in the fifteenth aspect, the VUV light irradiation is executed by use of a xenon excimer lamp whose center wavelength is 172 nm.

In accordance with a seventeenth aspect of the present invention, in the sixteenth aspect, the VUV light irradiation is executed for a period between 5 seconds and 60 seconds.

In accordance with an eighteenth aspect of the present invention, in the fifteenth aspect, the concentration of the oxygen gas in the oxygen-containing atmosphere is set to approximately 20% (volume) when the VUV light irradiation is executed.

In accordance with a nineteenth aspect of the present invention, there is provided a manufacturing device of a semiconductor device comprising: a container formed of quartz which stores one or more semiconductor circuit boards hermetically for forming an insulation oxide layer on the surface of each semiconductor circuit board; one or more inlet holes for supplying oxygen gas and nitrogen gas to inside the container; an outlet hole for evacuating gas from the container; and one or more VUV (Vacuum UltraViolet) light sources which are provided to the outer surface of the container.

In accordance with a twentieth aspect of the present invention, in the nineteenth aspect, the VUV light source is a xenon excimer lamp whose center wavelength is 172 nm.

### BRIEF DESCRIPTION OF THE DRAWINGS

The objects and features of the present invention will become more apparent from the consideration of the following detailed description taken in conjunction with the accompanying drawings, in which:

FIGS. 1A and 1B are graphs showing a result of an experiment concerning the removal of organic substances from a semiconductor circuit board which has been conducted by the present inventor, in which FIG. 1A shows the amount of organic substances on the surface of the semiconductor circuit board in conventional conditions and FIG. 1B shows the amount of the organic substances in conditions according to an embodiment of the present invention;

FIGS. 2A and 2B are graphs showing examples of temperature control patterns which are employed in a semiconductor device manufacturing method in accordance with an embodiment of the present invention;

FIG. 3 is a graph showing an example of a temperature control pattern according to the embodiment which is employed for removing phthalates and adipates from the surface of the semiconductor circuit board;

FIGS. 4A and 4B are graphs showing semiconductor device manufacturing methods in accordance with embodiments of the present invention, in which VUV (Vacuum UltraViolet) light irradiation steps are employed;

FIG. 5A is a schematic diagram showing an example of a semiconductor device manufacturing device in accordance with an embodiment of the present invention;

FIG. 5B is a schematic diagram showing a VUV light source which is employed in the semiconductor device manufacturing device of FIG. 5A;

FIG. 6 is a schematic diagram showing a configuration for leak current measurement which was executed by the present inventor; and

FIG. 7 is a graph showing electrical characteristics (V-I relationships) of gate oxide layers manufactured according to the present invention and a conventional technique.

### DESCRIPTION OF THE PREFERRED EMBODIMENTS

Referring now to the drawings, a description will be given in detail of preferred embodiments in accordance with the present invention.

In the semiconductor device manufacturing method in accordance with an embodiment of the present invention, before a step for forming a gate oxide layer (insulation oxide layer) on a semiconductor circuit board, the semiconductor circuit board is held in an atmosphere containing oxygen gas at preset temperature for a preset period, in order to remove organic impurities from the semiconductor circuit board. If the organic impurities (organic substances) are adhering to the surface of the semiconductor circuit board by physical adsorption, the organic impurities ought to be removed easily by holding the semiconductor circuit board at a temperature around 400° C. since the desorption temperature (i.e. the boiling point) of ordinary organic substances is lower than 400° C. However, there is a possibility that some organic substances are bonding to the semiconductor circuit board by chemical adsorption, and in such cases, the organic substances can not be removed only by holding the semiconductor circuit board around 400° C. Example of such organic substances which can not be removed by the temperature around 400° C. include the aforementioned adipates (DBA (di-butyl adipate), DOA (DEHA) (di-2-ethylhexyl adipate), etc.).

If the temperature in which the semiconductor circuit board is held for a preset period for the desorption of the organic substances (hereafter referred to as “temperature X”) is set to 750° C. or higher, the desorption of the organic substances from the semiconductor circuit board (substrate) becomes difficult, since there is a strong possibility that Si-C bonds are formed between the semiconductor circuit board and the organic substances before the desorption of the organic substances and thereby the organic substances adhere to the semiconductor circuit board by chemical adsorption. On the other hand, if the temperature X is set to 400° C. or lower, it is impossible to remove the organic substances (adipates etc.) from the semiconductor circuit board successfully. Therefore, in the semiconductor device manufacturing method in accordance with the embodiment of the present invention, the temperature X is set as 400° C.<X<750° C. According to experiments which have been conducted by the present inventor, the organic substances including the adipates could be removed from the semiconductor circuit board successfully by holding the semiconductor circuit board in an atmosphere containing oxygen gas for a preset period at the temperature X (400° C.<X<750° C.). According to the results of the experiments, it is preferable that the temperature X should be set between 450° C. and 700° C. for ensuring the removal of the organic substances including adipates, and more preferably, the temperature X should be set between 500° C. and 650° C.

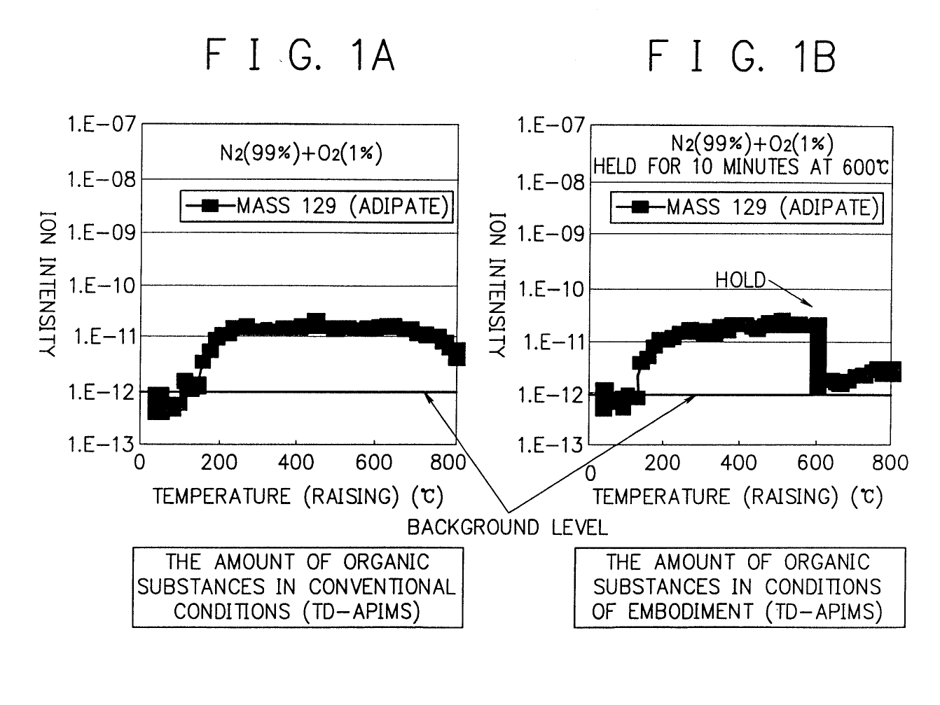

FIGS. 1A and 1B are graphs showing a result of an experiment concerning the removal of the organic substances (adipates) from the semiconductor circuit board, which has been conducted by the present inventor. FIG. 1A shows the amount of organic substances on the surface of the semiconductor circuit board in conventional conditions, and FIG. 1B shows the amount of organic substances on the surface of the semiconductor circuit board in conditions according to the embodiment of the present invention. In both cases, the amount of organic substances was measured by means of TD-APIMS (Thermal Desorption-Atmospheric Pressure Ion Mass Spectroscopy) raising the temperature of the semiconductor circuit board in an atmosphere of atmospheric pressure containing nitrogen gas (99%) and oxygen gas (1%). The temperature raising rate was approximately 20° C./minute in both cases. In the case of FIG. 1B, the semiconductor circuit board was held in the atmosphere at 600° C. for 10 minutes, thereby the organic substances (adipates) could be removed almost perfectly.

The length of the period for holding the semiconductor circuit board in the oxygen-containing atmosphere at the temperature X (400° C. <X<750° C.) should be set between 5 minutes and 10 minutes. According to experiments conducted by the present inventor, when the period was set shorter than 5 minutes, the organic substances could not be removed enough from the semiconductor circuit board. On the other hand, when the period was set longer than 10 minutes, oxidation of the surface of the semiconductor circuit board progressed too much. For example, even when a gate oxide layer of a thickness of 4 nm was supposed to be formed, an oxide layer (hereafter referred to as “initial oxide layer”) of a thickness of 0.5˜1 nm was formed by the period longer than 10 minutes. If such an initial oxide layer is formed before the gate oxide layer formation step, the formation of a very thin and uniform gate oxide layer becomes difficult. Therefore, it is preferable that the length of the period for holding the semiconductor circuit board in the oxygen-containing atmosphere at the temperature X (400° C.<X <750° C.) should be set between 5 minutes and 10 minutes.

The concentration of the oxygen gas in the oxygen-containing atmosphere employed in the step for holding the semiconductor circuit board in the oxygen-containing atmosphere at the temperature X (400° C. <X<750° C.) (hereafter referred to as a “holding step”) should be set between 0.5% and 1.0% (by volume). According to experiments conducted by the present inventor, when the concentration of the oxygen gas was set lower than 0.5%, the organic substances on the surface of the semiconductor circuit board were not decomposed enough and thereby some of the organic substances remained on the surface. If the gate oxide layer formation step is executed in such a situation, a gate oxide layer of poor electrical characteristics and low reliability is formed, and thus a semiconductor device having satisfactory electrical characteristics and reliability can not be obtained. On the other hand, when the concentration of the oxygen gas was set higher than 1.0%, oxidation of the surface of the semiconductor circuit board progressed too much and thereby an initial oxide layer of a thickness of 0.5˜1 nm was formed. If such an initial oxide layer exists on the surface of the semiconductor circuit board before the gate oxide layer formation step, the formation of a very thin and uniform gate oxide layer becomes difficult. By setting the oxygen gas concentration between 0.5% and 1.0%, the organic substances can be removed successfully from the surface of the semiconductor circuit board without causing the progress of the surface oxidation. Therefore, in order to remove the organic substances efficiently and attain the formation of a very thin and uniform gate oxide layer (by preventing the progress of the surface oxidation), it is preferable that the concentration of the oxygen gas in the oxygen-containing atmosphere in the holding step should be set between 0.5% and 1.0% (by volume).

After the holding step, the temperature of the semiconductor circuit board from which the organic substances have been removed is raised to a preset temperature Y for the gate oxide layer formation step. At the temperature Y, the semiconductor circuit board is held in an oxygen-abundant atmosphere (O₂+N₂, for example) for a preset period so that a gate oxide layer will be formed thereon. The temperature Y for the gate oxide layer formation step should be set between 800° C. and 850° C. If the temperature Y is set higher than 850° C., the possibility of damages occurring to the semiconductor device inside the semiconductor circuit board becomes high. On the other hand, if the temperature Y is set lower than 800° C., the gate oxide layer does not grow enough. In the semiconductor device manufacturing method of the embodiment, the organic substances on the surface of the semiconductor circuit board are removed enough in the holding step, and the temperature of the semiconductor circuit board is raised to the preset temperature Y (800° C. ≦Y≦850° C.), and thereafter the gate oxide layer is formed on the semiconductor circuit board by holding the semiconductor circuit board in an oxygen-abundant atmosphere for a preset period. Therefore, a very thin and uniform gate oxide layer can be formed on the surface of the semiconductor circuit board.

Preferably, the heating-up process from the temperature X to the temperature Y should be conducted in an inert gas atmosphere, thereby oxidation of the semiconductor circuit board in the heating-up process can be reduced, thereby a thinner and uniform gate oxide layer can be obtained in the following gate oxide layer formation step. One or more gasses selected from nitrogen gas, argon gas, helium gas and xenon gas are used for the inert gas atmosphere, for example.

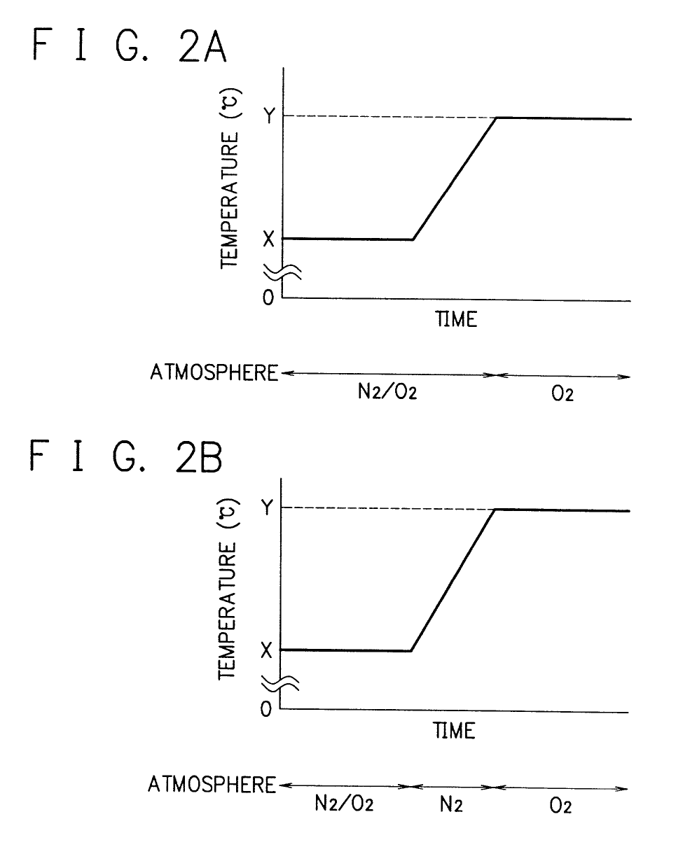

FIGS. 2A and 2B are graphs showing examples of temperature control patterns which are employed in the semiconductor device manufacturing method in accordance with the embodiment of the present invention. In the case of FIG. 2A, the semiconductor circuit board is held in an oxygen-containing atmosphere (N₂ (99% by volume)+O₂ (1% by volume), for example) at the temperature X for a preset period, and thereafter the temperature is raised to the temperature Y. Thereafter, the atmosphere around the semiconductor circuit board is changed into an oxygen-abundant atmosphere, and thereafter the semiconductor circuit board is held in the oxygen-abundant atmosphere at the temperature Y for a preset period so that the gate oxide layer will be formed.

As mentioned above, it is preferable that the heating-up process from the temperature X to the temperature Y should be conducted in an inert gas atmosphere. FIG. 2B is a graph showing such an example, in which a nitrogen gas atmosphere is employed. By use of such an inert gas atmosphere, oxidation of the semiconductor circuit board in the heating-up process can be reduced. Incidentally, the inert gas atmosphere can also be implemented by inert gas other than nitrogen gas or a combination of two or more inert gasses.

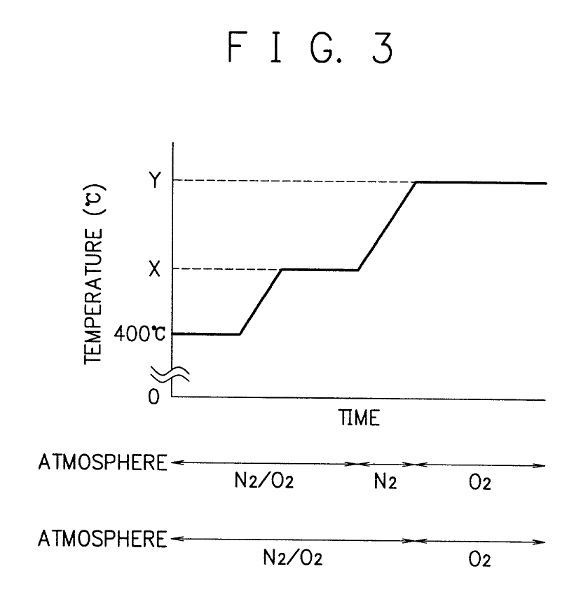

There are a wide variety of organic impurities in the air, therefore, two or more kinds of organic impurities are generally adhering to the surface of the semiconductor circuit board. For example, when phthalates in addition to the adipates are adhering to the surface of the semiconductor circuit board, the two types of organic impurities can be removed by a temperature control pattern which is shown in FIG. 3. In the case of FIG. 3, the phthalates are removed by holding the semiconductor circuit board at 400° C. in an oxygen-containing atmosphere for a preset period, and thereafter the adipates are removed by holding the semiconductor circuit board at the temperature X in the oxygen-containing atmosphere for a preset period. By use of such a temperature control pattern, two or more kinds of organic impurities can also be removed correctly.

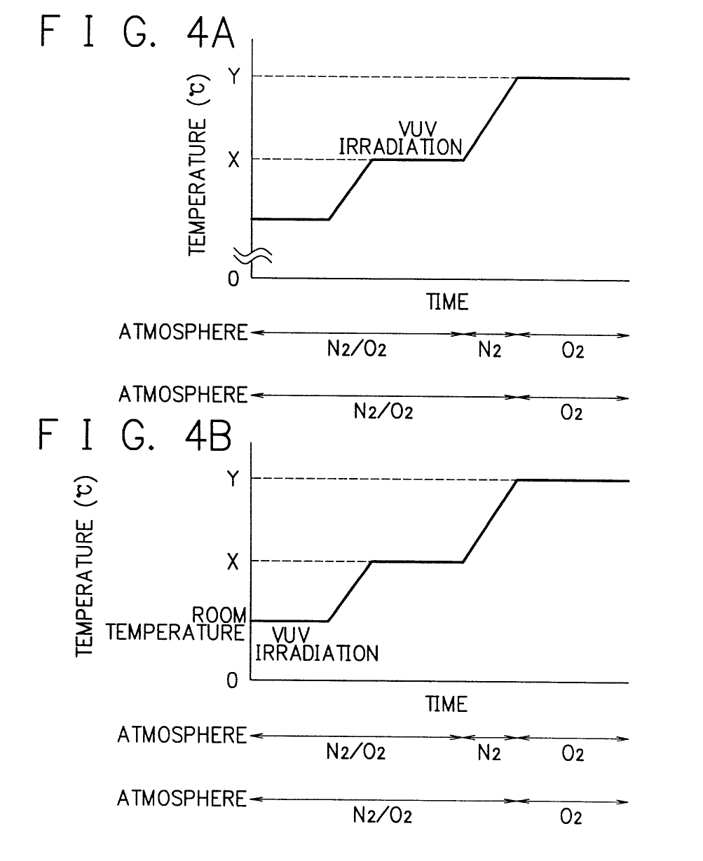

It is also possible to employ VUV (Vacuum UltraViolet) light irradiation in the holding step at the temperature X. FIG. 4A is a graph showing such an example, in which the semiconductor circuit board in the holding step at the temperature X in the oxygen-containing atmosphere is irradiated with VUV light having a center wavelength of 172 nm (Xe excimer lamp), thereby organic impurities are removed effectively from the surface of the semiconductor circuit board. By use of the VUV light irradiation, the organic substances can be removed more quickly, thereby the time necessary for manufacturing the semiconductor devices can be shortened and thereby the productivity can be raised.

By the VUV light irradiation, oxygen atoms (O) are generated in the oxygen-containing atmosphere. The oxygen atoms (O) are generated in two chemical reactions: a chemical reaction in which oxygen molecules (O₂) in the oxygen-containing atmosphere are directly decomposed into oxygen atoms (O) (equation (1)), and a chemical reaction in which oxygen molecules (O₂) in the oxygen-containing atmosphere change into ozone (O₃) and thereafter change into oxygen atoms (O) (equation (2)), therefore, the oxygen atoms (O) are generated efficiently. The excited oxygen atoms (O) are applied to the surface of the semiconductor circuit board and thereby the organic impurities are decomposed.

O₂→(O) (1)

O₂→O₃→(O) (2)

According to experiments conducted by the present inventor, the length of the period of the VUV light irradiation should be set between 5 seconds and 60 seconds. Preferably, the concentration of oxygen gas in the oxygen-containing atmosphere in the VUV light irradiation step should be set around 20%.

It is also possible to execute the VUV light irradiation (center wavelength: 172 nm) in the oxygen-containing atmosphere at temperature between room temperature and 400° C. and thereafter execute the holding step at the temperature X (400° C.<X<750° C.). FIG. 4B is a graph showing such an example, in which the VUV light irradiation is executed at room temperature. In the above chemical reactions (1) and (2), the reaction (1) is dominant, therefore, the removal of organic substances can be attained reducing the formation of an oxide layer on the surface of the semiconductor circuit board. Especially in the case where the VUV light irradiation is executed at room temperature, the formation of the oxide layer can be avoided almost perfectly.

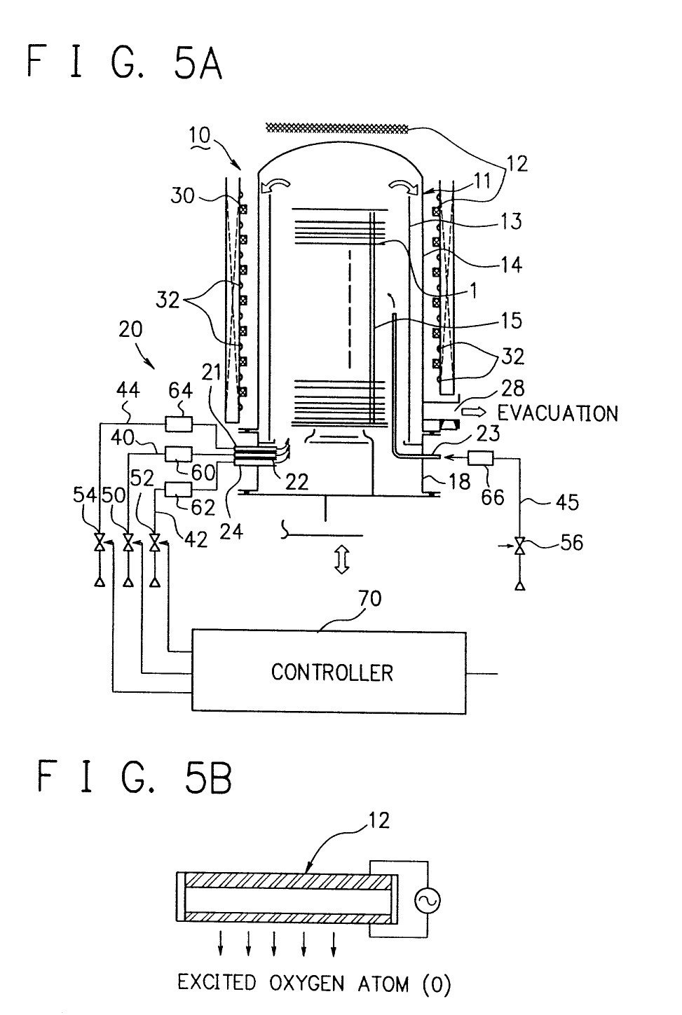

FIG. 5A is a schematic diagram showing an example of a semiconductor device manufacturing device in accordance with an embodiment of the present invention, which is capable of executing the holding step in the oxygen-containing atmosphere at the temperature X and the VUV light irradiation step in order to remove the organic impurities from the semiconductor circuit board. The semiconductor device manufacturing device 10 shown in FIG. 5A includes a core tube 11 (a container composed of an inner tube 13 and an outer tube 14), VUV light sources 12, a wafer holder 15, a gas supply system 20, inlet holes 21, 22, 23 and 24, an outlet hole 28, a heat insulation layer 30, a heater 32, gas pipes 40, 42, 44 and 46, gas flow control valves 50, 52, 54 and 56, mass-flow meters 60, 62, 64 and 66, and a controller 70.

The core tube 11, which is formed of quartz, stores the semiconductor circuit boards 1 hermetically for the formation of the gate oxide layers. Oxygen gas and nitrogen gas are supplied to the core tube 11 through the inlet holes 21 and 22. The VUV light sources 12 are provided to the outer surface of the core tube 11 so as to surround the semiconductor circuit boards 1 which are held by the wafer holder 15. By such setting of the VUV light sources 12, the VUV light irradiation can be executed efficiently without the need of moving the semiconductor circuit boards 1 and the VUV light irradiation can be executed regardless of the temperature inside the core tube 11. The semiconductor device manufacturing device 10 is used not only for the VUV light irradiation but for holding the semiconductor circuit boards 1 at a fixed temperature (the temperature X for removing the organic impurities including adipates, for example), for forming the gate oxide layers on the semiconductor circuit boards 1 at the temperature Y, etc.

The core tube 11 is closed hermetically in the holding step at the temperature X and in the gate oxide layer formation step at the temperature Y. Incidentally, while the VUV light sources 12 are placed at the top and the side of the core tube 11 in the example of FIG. 5A, the arrangement of the VUV light sources 12 are not limited to the example as long as the excited oxygen atoms can be applied to the surfaces of the semiconductor circuit boards 1. FIG. 5B is a schematic diagram showing a VUV light source 12 which is employed in the semiconductor device manufacturing device 10 of FIG. 5A. As the VUV light source 12, a xenon excimer lamp whose center wavelength is 172 nm is preferably used, for example. The wavelengths of the VUV light emitted by the VUV light source 12 have a certain distribution, therefore, actually, VUV light of wavelengths of 165˜179 nm is emitted by the VUV light source 12.

By the VUV light irradiation into the oxygen-containing atmosphere in the core tube 11, oxygen atoms are generated efficiently and thereby the organic impurities (phthalic acid, phthalates, etc.) adhering to the surfaces of the semiconductor circuit boards 1 are decomposed efficiently. Even if some of the organic impurities remained after the VUV light irradiation step, the core tube 11 is heated up by the heater 32 into the temperature X and the semiconductor circuit boards 1 are held in the oxygen-containing atmosphere at the temperature X for a preset period (holding step) and thereby the remaining organic impurities are removed almost perfectly. As described above, by use of the semiconductor device manufacturing device 10 in accordance with the embodiment of the present invention, the small amount of organic impurities adhering to the surfaces of the semiconductor circuit boards 1 can be removed efficiently, by the combination of the oxygen-containing atmosphere, the appropriate temperature and the VUV light irradiation.

In the following, an example of an experiment indicating the effects of the semiconductor device manufacturing method and the semiconductor device manufacturing device in accordance with the embodiment will be described in detail. In the experiment, electrical characteristics of a gate oxide layer formed according to the present invention was measured.

A semiconductor circuit board to which adipates (DBA (di-butyl adipate), DOA (DEHA) (di-2-ethylhexyl adipate), etc.) had been adhering was put in the core tube 11 at a temperature of 600° C., and the organic impurities on the surface of the semiconductor circuit board were removed by holding the semiconductor circuit board in an oxygen-containing atmosphere (N₂ (99%), O₂ (1%)) at 600° C. for 10 minutes. Subsequently, the atmosphere inside the core tube 11 was changed into a nitrogen gas atmosphere (N₂: 100%) and the temperature of the nitrogen gas atmosphere was raised to 800° C. at a rate of 80˜100° C./min. Thereafter, the semiconductor circuit board was held in an oxygen-abundant atmosphere at 800˜850° C. for 5˜10 minutes (wet oxidation), and thereby a gate oxide layer of a thickness of approximately 4 nm was formed on the semiconductor circuit board.

As a control experiment, an equivalent semiconductor circuit board to which adipates had been adhering was put in the core tube 11 at a temperature of 400° C., and the temperature inside the core tube 11 was raised to 800° C. at a rate of 5˜10° C./min in a nitrogen gas atmosphere (N₂: 100%). Subsequently, the atmosphere inside the core tube 11 was changed into an oxide-abundant atmosphere, and thereafter the semiconductor circuit board was held in the oxygen-abundant atmosphere at 800˜850° C. for 5˜10 minutes (wet oxidation) in the same way as the above example, thereby a gate oxide layer of a thickness of approximately 4 nm was formed on the semiconductor circuit board.

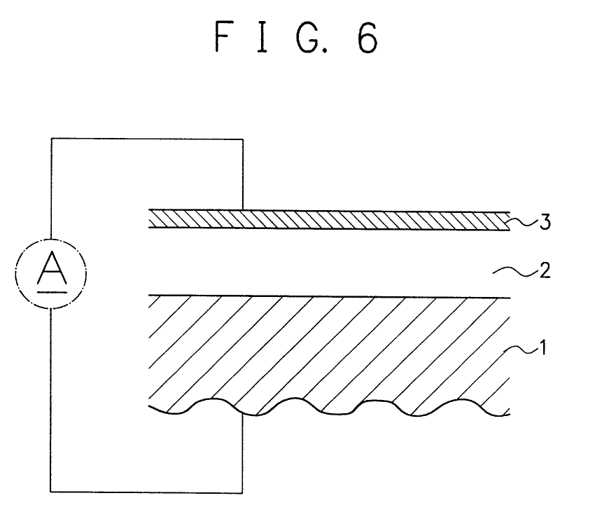

With regard to each of the two semiconductor circuit boards which have been manufactured as above, an electrode (pad) was formed on the gate oxide layer, and a leak current which passes between the electrode and metal part of the semiconductor circuit board through the gate oxide layer was measured. FIG. 6 shows a configuration for the leak current measurement, in which voltage was applied between the electrode 3 and the metal part of the semiconductor circuit board 1, and leak current passing through the gate oxide layer 2 was measured.

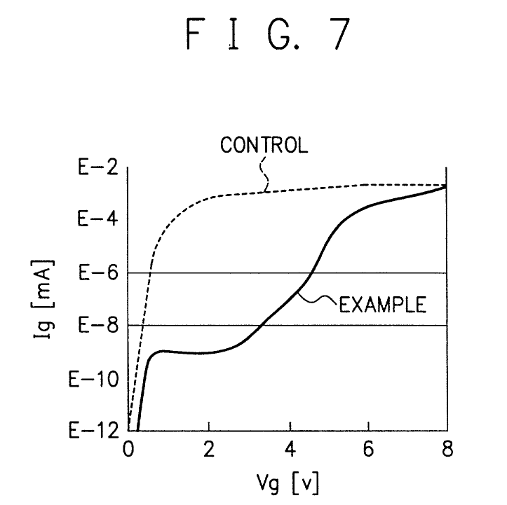

FIG. 7 is a graph showing the relationship between the voltage and the leak current when the voltage applied between the electrode 3 and the metal part of the semiconductor circuit board 1 was varied. Referring to FIG. 7, in the case where the holding step was not executed (control), the leak current Ig was saturated by a low voltage Vg of about 1 V, whereas the leak current Ig was not saturated until the voltage Vg was raised to about 6 V in the case where the holding step was executed before the gate oxide layer formation step. Therefore, by the holding step in accordance with the embodiment of the present invention, the organic impurities on the surface of the semiconductor circuit board could be removed successfully and thereby a gate oxide layer having high insulation resistance could be formed.

While the semiconductor device manufacturing method and the semiconductor device manufacturing device in accordance with the above embodiments of the present invention were employed for the formation of a gate oxide layer on a semiconductor circuit board, the application of the present invention is not limited to the gate oxide layers but the present invention can widely be used for the formation of insulation oxide layers.

As set forth hereinabove, in the semiconductor device manufacturing method in accordance with the embodiment of the present invention, before an insulation oxide layer formation step, the semiconductor circuit board is held in an atmosphere containing oxygen gas at temperature X (400° C.<X<750° C.) for a preset period (holding step).

If the temperature X is set to 750° C. or higher, Si-C bonds tend to be formed between the semiconductor circuit board and organic substances before the desorption of the organic substances from the semiconductor circuit board, thereby the organic substances tend to adhere to the semiconductor circuit board by chemical adsorption, and thereby the desorption of the organic substances from the semiconductor circuit board becomes difficult. If the temperature X is set to 400° C. or lower, it is impossible to remove the organic substances (adipates etc.) from the semiconductor circuit board successfully. By holding the semiconductor circuit board in an oxygen-containing atmosphere at the temperature X (400° C.<X<750° C.) for a preset period, appropriate thermal energy can be applied to the organic substances on the surface of the semiconductor circuit board and thereby the organic substances including adipates can be removed successfully from the semiconductor circuit board. For ensuring the removal of the organic substances including adipates, the temperature X is preferably set between 450° C. and 700° C., and more preferably, the temperature X is set between 500° C. and 650° C. By the removal of the organic substances, a very thin and uniform insulation oxide layer (gate oxide layer etc.) having excellent electrical characteristics and reliability can be formed on the semiconductor circuit board, and thereby a semiconductor device having satisfactory electrical characteristics and reliability can be manufactured.

Preferably, the preset period for the holding step is set between 5 minutes and 10 minutes.

If the period is set shorter than 5 minutes, the organic substances can not be removed enough. If the period is set longer than 10 minutes, the surface oxidation progresses too much and thereby the initial oxide layer is formed. For example, even in the case where a gate oxide layer of a thickness of 4 nm is supposed to be formed, an initial oxide layer of a thickness of 0.5 nm or more is preliminarily formed by the holding step period longer than 10 minutes, thereby the formation of a very thin and uniform insulation oxide layer becomes difficult. Therefore, by setting the holding step period between 5 minutes and 10 minutes, the organic substances on the surface of the semiconductor circuit board can be removed successfully without causing the progress of the surface oxidation.

Preferably, the concentration of the oxygen gas in the oxygen-containing atmosphere for the holding step is set between 0.5% (volume) and 1.0% (volume).

If the oxygen gas concentration is set lower than 0.5%, the organic substances on the surface of the semiconductor circuit board can not be decomposed enough and some of them remain on the surface, thereby an insulation oxide layer of poor electrical characteristics and low reliability is formed in the following insulation oxide layer formation step, and thereby electrical characteristics and reliability of the semiconductor device is necessitated to be low. If the oxygen gas concentration is set higher than 1.0%, the surface oxidation progresses too much and thereby an initial oxide layer of a thickness of 0.5 nm or more is preliminarily formed, thereby the formation of a very thin and uniform insulation oxide layer by the following insulation oxide layer formation step becomes difficult. Therefore, by setting the oxygen gas concentration between 0.5% (volume) and 1.0% (volume), the organic substances on the surface of the semiconductor circuit board can be removed successfully reducing the progress of the surface oxidation.

Preferably, the temperature X is set so as to be suitable for removing adipates (DBA (di-butyl adipate), DOA (DEHA) (di-2-ethylhexyl adipate), etc.) which are found on the surface of the semiconductor circuit board.

If adipates adhering to the surface of the semiconductor circuit board exist, the surface of the semiconductor circuit board becomes coarse, thereby insulation resistance and reliability of the insulation oxide layer to be formed in the following step are necessitated to be deteriorated. By removing the adipates enough before the insulation oxide layer formation step, electrical characteristics of the insulation oxide layer can be improved and thereby a semiconductor device having improved electrical characteristics and reliability can be manufactured.

Preferably, after the holding step, the temperature of the semiconductor circuit board is raised to Y (800° C.≦Y≦850° C.) in an inert gas atmosphere, and thereafter the semiconductor circuit board is held in an oxygen-abundant atmosphere at the temperature Y for a preset period so that the insulation oxide layer will be formed on the surface of the semiconductor circuit board.

The semiconductor circuit board from which the organic substances have been removed in the holding step is heated up from the temperature X to the temperature Y in the inert gas atmosphere, thereby oxidation of the semiconductor circuit board in the heating-up process can be reduced, and thereby a thinner and uniform insulation oxide layer can be obtained in the insulation oxide layer formation step.

Preferably, before the holding step, the semiconductor circuit board is held in an atmosphere containing oxygen gas at temperature around 400° C. for a preset period.

By holding the semiconductor circuit board at temperature around 400° C., organic substances whose boiling points are not very high (400° C. or less) can preliminarily be removed enough before conducting the holding step for removing the organic substances such as adipates having boiling points higher than 400° C., thereby the organic substances can be removed from the semiconductor circuit board almost perfectly.

Preferably, in the holding step, the semiconductor circuit board is irradiated with VUV (Vacuum UltraViolet) light. The concentration of the oxygen gas in the oxygen-containing atmosphere is preferably set to approximately 20% (volume) during the VUV light irradiation. The VUV light irradiation is preferably executed by use of a xenon excimer lamp whose center wavelength is 172 nm. The length of the VUV light irradiation period is preferably set between 5 seconds and 60 seconds.

By the VUV light irradiation, the efficiency of the removal of the organic substances can be improved and thereby the productivity of the semiconductor devices can be raised.

Preferably, before the holding step, the semiconductor circuit board placed in an oxygen-containing atmosphere is irradiated with VUV light at temperature between room temperature and 400° C. for a preset period. The concentration of the oxygen gas in the oxygen-containing atmosphere is preferably set to approximately 20% (volume) during the VUV light irradiation. The VUV light irradiation is preferably executed by use of a xenon excimer lamp whose center wavelength is 172 nm. The length of the VUV light irradiation period is preferably set between 5 seconds and 60 seconds.

By the VUV light irradiation at temperature between room temperature and 400° C., the organic substances can be removed reducing the formation of an oxide layer on the surface of the semiconductor circuit board.

The semiconductor device manufacturing device in accordance with the present invention includes: a container formed of quartz which stores one or more semiconductor circuit boards hermetically for forming an insulation oxide layer on the surface of each semiconductor circuit board; one or more inlet holes for supplying oxygen gas and nitrogen gas to inside the container; an outlet hole for evacuating gas from the container; and one or more VUV (Vacuum UltraViolet) light sources which are provided to the outer surface of the container. The VUV light source is preferably implemented by a xenon excimer lamp whose center wavelength is 172 nm.

By the semiconductor device manufacturing device, VUV light can be applied to the oxygen gas inside the container and thereby oxygen atoms can be generated. Due to the oxygen atoms, organic substances adhering to the surface of the semiconductor circuit board can be decomposed and removed efficiently, thereby very thin and uniform insulation oxide layers can be formed on the semiconductor circuit boards, and thereby semiconductor devices having satisfactory electrical characteristics and reliability can be manufactured. The VUV light sources provided to the outer surface of the container emits the VUV light through the container which is formed of quartz, therefore, the VUV light irradiation can be executed regardless of the temperature inside the container.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A manufacturing method of a semiconductor device including a step for forming an insulation oxide layer on a semiconductor circuit board, wherein before the insulation oxide layer formation step, the semiconductor circuit board is held in an atmosphere containing oxygen gas at temperature X (400° C.<X<750° C.) for a preset period.

2. A manufacturing method of a semiconductor device as claimed in claim 1, wherein the preset period is set between 5 minutes and 10 minutes.

3. A manufacturing method of a semiconductor device as claimed in claim 1, wherein the concentration of the oxygen gas in the oxygen-containing atmosphere is set between 0.5% (volume) and 1.0% (volume).

4. A manufacturing method of a semiconductor device as claimed in claim 1, wherein the temperature X is set so as to be suitable for removing adipates which are found on the surface of the semiconductor circuit board.

5. A manufacturing method of a semiconductor device as claimed in claim 4, wherein the temperature X is set so as to be suitable for removing DBA (di-butyl adipate).

6. A manufacturing method of a semiconductor device as claimed in claim 4, wherein the temperature X is set so as to be suitable for removing DOA (DEHA) (di-2-ethylhexyl adipate).

7. A manufacturing method of a semiconductor device as claimed in claim 1, wherein the temperature X is set between 450° C. and 700° C.

8. A manufacturing method of a semiconductor device as claimed in claim 7, wherein the temperature X is set between 500° C. and 650° C.

9. A manufacturing method of a semiconductor device as claimed in claim 1, wherein after the step for holding the semiconductor circuit board in the oxygen-containing atmosphere at the temperature X for the preset period, the temperature of the semiconductor circuit board is raised to Y (800° C.≦Y≦850° C.) in an inert gas atmosphere, and thereafter the semiconductor circuit board is held in an oxygen-abundant atmosphere at the temperature Y for a preset period so that the insulation oxide layer will be formed on the surface of the semiconductor circuit board.

10. A manufacturing method of a semiconductor device as claimed in claim 1, wherein before the step for holding the semiconductor circuit board in the oxygen-containing atmosphere at the temperature X for the preset period, the semiconductor circuit board is held in an atmosphere containing oxygen gas at temperature around 400° C. for a preset period.

11. A manufacturing method of a semiconductor device as claimed in claim 1, wherein in the step for holding the semiconductor circuit board in the oxygen-containing atmosphere at the temperature X for the preset period, the semiconductor circuit board is irradiated with VUV (Vacuum UltraViolet) light.

12. A manufacturing method of a semiconductor device as claimed in claim 11, wherein the VUV light irradiation is executed by use of a xenon excimer lamp whose center wavelength is 172 nm.

13. A manufacturing method of a semiconductor device as claimed in claim 12, wherein the VUV light irradiation is executed for a period between 5 seconds and 60 seconds.

14. A manufacturing method of a semiconductor device as claimed in claim 11, wherein the concentration of the oxygen gas in the oxygen-containing atmosphere is set to approximately 20% (volume) when the VUV light irradiation is executed.

15. A manufacturing method of a semiconductor device as claimed in claim 1, wherein before the step for holding the semiconductor circuit board in the oxygen-containing atmosphere at the temperature X for the preset period, the semiconductor circuit board placed in an oxygen-containing atmosphere is irradiated with VUV (Vacuum UltraViolet) light at temperature between room temperature and 400° C. for a preset period.

16. A manufacturing method of a semiconductor device as claimed in claim 15, wherein the VUV light irradiation is executed by use of a xenon excimer lamp whose center wavelength is 172 nm.

17. A manufacturing method of a semiconductor device as claimed in claim 16, wherein the VUV light irradiation is executed for a period between 5 seconds and 60 seconds.

18. A manufacturing method of a semiconductor device as claimed in claim 15, wherein the concentration of the oxygen gas in the oxygen-containing atmosphere is set to approximately 20% (volume) when the VUV light irradiation is executed.

19. A manufacturing device of a semiconductor device comprising:
a container formed of quartz which stores one or more semiconductor circuit boards hermetically for forming an insulation oxide layer on the surface of each semiconductor circuit board;
one or more inlet holes for supplying oxygen gas and nitrogen gas to inside the container;
an outlet hole for evacuating gas from the container; and
one or more VUV (Vacuum UltraViolet) light sources which are provided to the outer surface of the container.

20. A manufacturing device of a semiconductor device as claimed in claim 19, wherein the VUV light source is a xenon excimer lamp whose center wavelength is 172 nm.
